(19) United States
(12) Patent Application Publication
(10) Pub. No.: US 2022/0349082 A1
(43) Pub. Date: Nov. 3, 2022

(54) Coated Metal Alloy Substrate and Process for Production Thereof

(71) Applicant: Hewlett-Packard Development Company, L.P., Spring, TX (US)

(72) Inventors: Qingyong Guo, Shanghai (CN); Ya Cheng Chuang, Shanghai (CN); Yong-Jun Li, Shanghai (CN); Kuan-Ting Wu, Taipei City (TW)

(73) Assignee: Hewlett-Packard Development Company, L.P., Spring, TX (US)

(21) Appl. No.: 17/296,931

(22) PCT Filed: Aug. 12, 2019
(86) PCT No.: PCT/CN2019/100257

§ 371 Date: May 25, 2021

(51) Int. Cl. C25D 13/22; C25D 9/06; C25D 13/12; H05K 5/04; H05K 5/06

(52) U.S. Cl. CPC C25D 13/22; C25D 9/06; C25D 13/12; H05K 5/04; H05K 5/06; C25D 11/30

(57) ABSTRACT

A coated metal alloy substrate, a process for producing a coated metal alloy substrate, and an electronic device having a housing comprising a coated metal alloy substrate are described. The coated metal alloy substrate comprises an electrolytic sealing layer on the metal alloy substrate, and an electrophoretic deposition layer deposited on the electrolytic sealing layer.

Electronic devices, such as laptops and mobile phones, include various components located within a metal alloy housing. Such metal alloy housings are made of metal alloy substrates that provide sought after metallic lustre of the metal alloy enclosure. Such enclosures should be able to withstand wear and tear from regular use and exposure to the natural environment.

### BRIEF DESCRIPTION OF THE FIGURES

FIG. 1 is a flow chart showing an example of a process for producing a coated metal alloy substrate.

FIG. 2 is a flow chart showing an example of a process for producing a coated metal alloy substrate comprising the formation of a first layered surface.

FIG. 3 is flow chart showing an example of a process for producing a coated metal alloy substrate comprising the formation of a first treated surface.

FIGS. 4a and 4b are partial cross-sectional diagram showing an example of a coated metal alloy substrate.

FIG. 5 shows an example housing for a laptop.

The figures depict several examples of the present disclosure. It should be understood that the present disclosure is not limited to the examples depicted in the figures.

### DETAILED DESCRIPTION

Before the coated metal alloy substrate, process for producing a coated metal alloy substrate, and electronic device with a housing comprising a coated metal alloy substrate are disclosed and described, it is to be understood that this disclosure is not limited to the particular process details and materials disclosed herein because such process details and materials may vary somewhat. It is also to be understood that the terminology used herein is used for the purpose of describing particular examples. The terms are not intended to be limiting because the scope of the present disclosure is intended to be limited by the appended claims and equivalents thereof.

It is noted that, as used in this specification and the appended claims, the singular forms “a”, “an” and “the” include plural referents unless the context clearly dictates otherwise.

If a standard test is mentioned herein, unless otherwise stated, the version of the test to be referred to is the most recent at the time of filing this patent application.

As used herein, the term “about” is used to provide flexibility to a numerical range endpoint by providing that a given value may be “a little above” or “a little below” the endpoint. The degree of flexibility of this term can be dictated by the particular variable and would be within the knowledge of those skilled in the art to determine based on experience and the associated description herein.

Concentrations, amounts, and other numerical data may be expressed or presented herein in a range format. It is to be understood that such a range format is used merely for convenience and brevity and thus should be interpreted flexibly to include the numerical values explicitly recited as the limits of the range also to include all the individual numerical values or sub-ranges encompassed within that range as if each numerical value and sub-range is explicitly recited. As an illustration, a numerical range of “about 1 wt. % to about 5 wt. %” should be interpreted to include the explicitly recited values of about 1 wt. % to about 5 wt. % and also include individual values and subranges within the indicated range. Thus, included in this numerical range are individual values such as 2, 3.5, and 4 and sub-ranges such as from 1-3, from 2-4, and from 3-5, etc. This same principle applies to ranges reciting a single numerical value. Furthermore, such an interpretation should apply regardless of the breadth of the range or the characteristics being described.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list based on their presentation in a common group without indications to the contrary.

As used herein, the term “deposited” when used to refer to the location or position of a layer includes the term “disposed” or “coated”.

As used herein, the term “engraving” when used to refer to the formation of a chamfered edge includes the term “etching” or “cutting”.

As used herein, the term “comprises” has an open meaning, which allows other, unspecified features to be present. This term embraces, but is not limited to, the semi-closed term “consisting essentially of” and the closed term “consisting of”. Unless the context indicates otherwise, the term “comprises” may be replaced with either “consisting essentially of” or “consists of”.

Unless otherwise stated, any feature described herein can be combined with any other feature described herein.

The present inventors have found that coatings for metal alloy substrates can suffer from orange peeling, wherein the surface resembles an orange peel, thereby having a detrimental effect on the aesthetic and tactile properties of the metal alloy substrate surface. The present inventors have found that by applying a combination of coating layers described herein, an uneven surface or orange peeling can be avoided or at least mitigated. The present inventors have found that by coating a metal alloy substrate with an electrolytic sealing layer and applying an electrophoretic deposition layer onto the electrolytic sealing layer a uniform electrophoretic deposition surface can be provided, and orange peeling can be reduced or eliminated altogether. The present inventors have also found that in some examples a robust corrosion resistant surface can be formed with good aesthetic and tactile properties. The application of the electrophoretic deposition layer directly onto the electrolytic sealing layer can also allow the application of a thicker electrophoretic deposition layer, due to good adhesion between the layers.

Coated Metal Alloy Substrate

In some examples there is provided a coated metal alloy substrate for an electronic device comprising an electrolytic sealing layer deposited on the metal alloy substrate; and an electrophoretic deposition layer deposited on the electrolytic sealing layer.

Metal Alloy Substrate

The metal alloy substrate may comprise a metal selected from aluminium, magnesium, lithium, titanium, niobium, zinc and alloys thereof. For example, the metal alloy substrate may comprise a metal alloy selected from an aluminium alloy, a magnesium alloy, a lithium alloy, a titanium alloy and stain steel. These metals may be light-weight and can provide a durable housing.

Generally, the metal alloy comprises a content of metal of at least about 75 wt. %. For example, when the metal alloy is a magnesium alloy, the magnesium alloy may comprise at least about 80 wt. % magnesium, or at least 85 wt. % magnesium, or at least about 90 wt. % of magnesium, based on the total weight of the metal alloy.

The magnesium alloy may further comprise aluminium, zinc, manganese, silicon, copper, a rare earth metal or zirconium. The aluminium content may be about 2.5 wt. % to about 13.0 wt. %. When the magnesium alloy comprises aluminium, then at least one of manganese, zirconium, or silicon is also present. Examples of magnesium alloys include AZ31, AZ31B, AZ61, AZ60, AZ80, AM60, AZ91D, LZ91, LZ14, ALZ691 alloys according to the American Society for Testing Materials standards.

In one example, the metal alloy comprises the components, based on the total weight of the metal alloy, AI: 0.02 wt. % to 9.7 wt. %, Zn: 0.02 wt. % to 1.4 wt. %, Mn: 0.02 wt. % to 0.5 wt. %, one or more component selected from Si: 0.02 wt. % to 0.1 wt. %, Fe: 0.004 wt. % to 0.05 wt. %, Ca: 0.0013 wt. % to 0.04 wt. %, Ni: 0.001 wt. % to 0.005 wt. %, Cu: 0.008 wt. % to 0.05 wt. %, Li: 9.0 wt. % to 14.3 wt. %, Zr: up to 0.002 wt. % and the balance being Mg and inevitable impurities.

### Insert Molded Metal Substrate

The metal alloy substrate may be an insert molded metal substrate to form a metal substrate with sections comprising a further material, such as plastics. For example, the insert molded metal substrate may be formed by using the metal substrate as a mold.

This metal mold may have a section into which a material, such as plastic, is injected to form a plastic insert. Plastics used for insert molded metal substrates may be selected from polybutylene terephthalate (PBT), polyphenylene sulfide (PPS), polyamide (nylon), polyphthalamide (PPA), acrylonitrile butadiene styrene (ABS), polyetheretherketone (PEEK), polycarbonate (PC) and acrylonitrile butadiene styrene with polycarbonate (ABS/PC) with 15 to 50 wt. % glass fibre filler.

### Chamfered Edge

The metal alloy substrate may comprise one chamfered edge or more than one chamfered edge. The one or more chamfered edges are formed by engraving the metal alloy substrate. The engraving process to form a chamfered edge can be carried out using a range of techniques including a computer numeric control (CNC) diamond cut or laser engraving process. The engraving process exposes a non-oxidized surface of the substrate. The non-oxidized surface of the substrate exposed in this way is an uncoated surface of the substrate that has not undergone substantial oxidation, so that, for example, it retains its metallic appearance.

By coating the non-oxidised surface of the metal alloy substrate formed by engraving with an electrolytic sealing layer and an electrophoretic deposition layer, it may be possible to both protect and retain the attractive, shiny appearance of the underlying metallic substrate. Unlike coatings formed by electroplating processes, the layer can protect the exposed, underlying surface from corrosion. The coated surfaces of the metal alloy substrate, including the chamfered edges disclosed herein can show good resistance as tested using a salt fog test, such as ASTM B117, particularly when compared to coating formed by electroplating.

### Electrolytic Sealing Layer

The electrolytic sealing layer comprises a metal salt selected from zinc oxide, chromium hydroxide Cr(OH)₃, potassium hydroxide, sodium carbonate, sodium silicate, and combinations thereof. For example the electrolytic sealing layer may comprise zinc oxide, potassium hydroxide, sodium carbonate and sodium silicate; or zinc oxide, potassium hydroxide and sodium carbonate; or zinc oxide and potassium hydroxide; or zinc oxide, sodium carbonate and sodium silicate; or zinc oxide, potassium hydroxide and sodium silicate; or zinc oxide and sodium silicate; or zinc oxide and sodium carbonate; or zinc oxide, chromium hydroxide, potassium hydroxide, sodium carbonate and sodium silicate; or zinc oxide, chromium hydroxide, potassium hydroxide and sodium carbonate; or zinc oxide, chromium hydroxide and potassium hydroxide; or zinc oxide, chromium hydroxide, sodium carbonate and sodium silicate; or zinc oxide, chromium hydroxide, potassium hydroxide and sodium silicate; or zinc oxide, chromium hydroxide and sodium silicate; or zinc oxide, chromium hydroxide, and sodium carbonate; or chromium hydroxide, potassium hydroxide and sodium carbonate; or chromium hydroxide and potassium hydroxide; or chromium hydroxide, sodium carbonate and sodium silicate; or chromium hydroxide, potassium hydroxide and sodium silicate; or chromium hydroxide and sodium silicate; or chromium hydroxide, and sodium carbonate; or zinc oxide, or chromium oxide.

In some examples the electrolytic sealing layer may comprise at least 70 wt % of zinc oxide, based on the total weight of the electrolytic sealing layer. For example, the electrolytic sealing layer may comprise zinc oxide in an amount of at least 75 wt. %, or at least 80 wt. %, or at least 85 wt. %, or at least 90 wt. %, or at least 95 wt. %, or at least 98 wt. %, based on the total weight of the electrolytic sealing layer.

In some examples the electrolytic sealing layer may comprise at least 70 wt % of chromium hydroxide, based on the total weight of the electrolytic sealing layer. For example, the electrolytic sealing layer may comprise chromium hydroxide in an amount of at least 75 wt. %, or at least 80 wt. %, or at least 85 wt. %, or at least 90 wt. %, or at least 95 wt. %, or at least 98 wt. %, based on the total weight of the electrolytic sealing layer.

In some examples the electrolytic sealing layer may comprise at least 70 wt % of a combination of chromium hydroxide and zinc oxide, based on the total weight of the electrolytic sealing layer. For example, the electrolytic sealing layer may comprise a combination of chromium hydroxide and zinc oxide in an amount of at least 75 wt. %, or at least 80 wt. %, or at least 85 wt. %, or at least 90 wt. %, or at least 95 wt. %, or at least 98 wt. %, based on the total weight of the electrolytic sealing layer.

The electrolytic sealing layer may have a thickness of from about 0.01 μm to about 3 μm, for example from about 0.05 μm to about 2.75 μm, or from about 0.1 μm to about 2.5 μm, or from about 0.2 μm to about 2.25 μm, or from about 0.3 μm to about 2.0 μm, or from about 0.4 μm to about 1.75 μm, or from about 0.5 μm to about 1.5 μm, or from about 0.75 μm to about 1.25 μm, or from about 0.9 μm to about 1.1 μm.

### Electrophoretic Deposition Layer

The electrophoretic deposition layer comprises an electrophoretic polymer selected from polyacrylic polymer, polyacrylamide-acrylic copolymer and epoxy-containing polymer.

The electrophoretic deposition layer may be transparent. In one example, the electrophoretic deposition layer is colourless. In another example, the electrophoretic polymer layer may comprise a colorant.

A “colorant” may be a material that imparts a colour to the electrophoretic deposition layer. As used herein, “colorant” includes pigments and dyes, such as those that impart colours, such as black, magenta, cyan, yellow and white to an electrophoretic deposition layer. The pigment particles may be dispersed throughout the electrophoretic deposition layer. The pigment may be selected from carbon black, titanium dioxide, clay, mica, talc, barium sulfate, calcium carbonate, synthetic pigment, pearl pigment, metallic powder, aluminium oxide, dye, graphene, graphite, pigment colorants, magnetic particles and an inorganic powder. Although the present description primarily exemplifies the use of pigment colorants, the term “pigment” can be used more generally to describe pigment colorants and also other pigments such as organometallics, ferrites and ceramics. In one example, the pigment is a dye. The dye may be dispersed throughout the electrophoretic deposition layer.

The colorant can be any colorant compatible with the electrophoretic polymer and useful for providing an electrophoretic deposition layer. For example, the colorant may be present as pigment particles, or may comprise a resin and a pigment. The pigments can be any of those standardly used in the art. In some examples, the colorant is selected from a cyan pigment, a magenta pigment, a yellow pigment and a black pigment. For example, pigments by Hoechst including Permanent Yellow DHG, Permanent Yellow GR, Permanent Yellow G, Permanent Yellow NCG-71, Permanent Yellow GG, Hansa Yellow RA, Hansa Brilliant Yellow 5GX-02, Hansa Yellow X, NOVAPERM® YELLOW HR, NOVAPERM® YELLOW FGL, Hansa Brilliant Yellow 10GX, Permanent Yellow G3R-01, HOSTAPERM® YELLOW H4G, HOSTAPERM® YELLOW H3G, HOSTAPERM® ORANGE GR, HOSTAPERM® SCARLET GO, Permanent Rubine F6B; pigments by Sun Chemical including L74-1357 Yellow, L75-1331 Yellow, L75-2337 Yellow; pigments by Heubach including DALAMAR® YELLOW YT-858-D; pigments by Ciba-Geigy including CROMOPHTHAL® YELLOW 3 G, CROMOPHTHAL® YELLOW GR, CROMOPHTHAL® YELLOW 8 G, IRGAZINE® YELLOW 5GT, IRGALITE® RUBINE 4BL, MONASTRAL® MAGENTA, MONASTRAL® SCARLET, MONASTRAL® VIOLET, MONASTRAL® RED, MONASTRAL® VIOLET; pigments by BASF including LUMOGEN® LIGHT YELLOW, PALIOGEN® ORANGE, HELIOGEN® BLUE L 690 IF, HELIOGEN® BLUE TBD 7010, HELIOGEN® BLUE K 7090, HELIOGEN® BLUE L 710 IF, HELIOGEN® BLUE L 6470, HELIOGEN® GREEN K 8683, HELIOGEN® GREEN L 9140; pigments by Mobay including QUINDO® MAGENTA, INDOFAST® BRILLIANT SCARLET, QUINDO® RED 6700, QUINDO® RED 6713, INDOFAST® VIOLET; pigments by Cabot including Maroon B STERLING® NS BLACK, STERLING® NSX 76, MOGUL® L; pigments by DuPont including TIPURE® R-101; and pigments by Paul Uhlich including UHLICH® BK 8200. If the pigment is a white pigment particle, the pigment particle may be selected from TiO₂, calcium carbonate, zinc oxide, and mixtures thereof. In some examples, the white pigment particle may comprise an alumina-TiO₂ pigment. In some examples the colorant may be Pacific Blue dye.

The colorant or pigment may be present in the electrophoretic deposition layer in an amount of from about 0.1 wt. % to about 15 wt. %, based on the total weight of the electrophoretic deposition layer. For example, the colorant or pigment may be present in the electrophoretic deposition layer in an amount from about 0.5 wt. % to about 13 wt. %, or from about 1 wt. % to about 12 wt. %, or from about 1.5 wt. % to about 10 wt. %, or from about 2 wt. % to about 9 wt. %, or from about 2.5 wt. % to about 8 wt. %, or from about 3 wt. % to about 7 wt. %, or from about 3.5 wt. % to about 6 wt. %, or from about 4 wt. % to about 5 wt. %, based on the total weight of the electrophoretic deposition layer. In some examples, the colorant or pigment particle may be present in the electrophoretic deposition layer in an amount of at least 5.5 wt. % based on the total weight of the electrophoretic deposition layer, for example at least 4.5 wt. % based on the total weight of the electrophoretic deposition layer.

In one example the electrophoretic deposition layer comprises, based on the total weight of the electrophoretic deposition layer, 10 wt. % polyacrylic copolymer resin, 0.1 wt. % Pacific Blue dye, 0.3 wt. % of an anionic surfactant, such as sodium dodecylbenzene and 89.6 wt. % de-ionized water.

The electrophoretic deposition layer may have a thickness of from about 5 μm to about 60 μm, for example from about 10 μm to about 55 μm, or from about 15 μm to about 50 μm, or from about 20 μm to about 45 μm, or from about 25 μm to about 40 μm, or from about 30 μm to about 35 μm.

### Passivation Layer

The passivation layer may be transparent. The passivation layer may comprise a chelating agent and a metal ion or chelated metal complex thereof, or a mixture of the chelating agent, the metal ion and the chelated metal complex. The chelated metal complex comprises a ligand coordinated to the metal ion. The ligand is the chelating agent.

The chelating agent may be selected from ethylenediaminetetraacetic acid (EDTA), ethylenediamine (EN), nitrilotriacetic acid (NTA), diethylenetriaminepenta(methylenephosphonic acid) (DTPPH), nitrilotris(methylenephosphonic acid) (NTMP), 1-hydroxyethane-1,1-diphosphonic acid (HEDP) and phosphoric acid. In one example, the chelating agent is DTPPH.

The metal ion is selected from an aluminium ion, a nickel ion, a chromium ion, a tin ion, an indium ion, and a zinc ion. In one example, the metal ion is selected from an aluminium ion, a nickel ion and a zinc ion.

In one example, the chelated metal complex may comprise DTPPH chelated to an aluminium ion. In another example, the chelated metal complex may comprise DTPPH chelated to a nickel ion. In a further example, the chelated metal complex may comprise DTPPH chelated to a zinc ion.

The passivation layer may have a thickness of from about 30 nm to about 3 μm, such as from about 200 nm to about 2 μm, or from about 500 nm to about 1 μm.

### Pre-Treatment of the Metal Alloy Substrate

### First Layered Surface

The metal alloy substrate may be pre-treated to form a first layered surface before application of the electrolytic sealing layer. The first layered surface may comprise a single layer or a combination of layers. The first layered surface may comprise an oxidized layer, a protective layer or a combination thereof.

When the first layered surface comprises an oxidized layer, this layer may comprise a preliminary passivation layer, an oxidized layer of the metallic substrate, or both an oxidized layer of the metallic substrate and a preliminary passivation layer. The preliminary passivation layer may also be referred to herein as an inorganic layer.

The inorganic layer may comprise a salt selected from a molybdate salt, a vanadate salt, a phosphate salt, a chromate salt, a stannate salt and a manganese salt. In one example, the inorganic layer comprises a phosphate salt. The inorganic layer may contain oxidic salts that can provide the first surface with a dark grey appearance. In one example, the inorganic layer may be non-transparent.

The oxidized layer of the metallic substrate may be a micro-arc oxide (MAO) layer, such as a micro-arc oxide layer of the magnesium alloy. For example, when the substrate comprises a magnesium alloy, the oxidized layer of the metallic substrate is an oxidized layer of the magnesium alloy. The micro-arc oxide layer may be obtainable from the method described herein.

The oxidized layer of the metallic substrate, including the micro-arc oxide layer, can have a thickness of from about 3 μm to about 15 μm, such as from about 5 μm to about 12 μm, from about 7 μm to about 10 μm. The inorganic layer may have a thickness of from about 0.5 μm to about 5 μm, such as from about 1 μm to about 4 μm, or about 2 μm to about 3 μm.

In one example, both an oxidized layer of the metallic substrate and an inorganic layer may be present. In one example, the inorganic layer can be deposited or coated on the surface of the metal alloy substrate.

In one example, the oxidized layer or the inorganic layer can be a single layer, wherein the oxidized layer is a micro-arc oxide layer. By itself, the micro-arc oxide layer or the passivation layer may prevent corrosion of the metal alloy substrate.

The first layered surface may further comprise at least one protective layer, such as two, three or four protective layers. Each protective layer may be selected from a primer coating layer, a base coating layer, powder coating layer and a top coating layer. The protective layer may be deposited or coated directly on to the oxidized layer or the inorganic layer. Each of these protective layers may be made of different materials and may provide different functionality, such as heat resistance, hydrophobicity, and anti-bacterial properties.

The primer coating layer may comprise a polyurethane or a filler selected from carbon black, titanium dioxide, clay, mica, talc, barium sulfate, calcium carbonate, a synthetic pigment, a metallic powder, aluminium oxide, carbon nanotubes (CNTs), graphene, graphite, and an organic powder. The organic powder may, for example, be an acrylic, a polyurethane, a polyamide, a polyester or an epoxide. The primer coating layer may, for example, comprise a polyurethane and a filler as described above.

A heat resistant material may be included in the primer coating layer. In an example, the primer coating layer contains a heat resistant material, a filler as described above and may further comprise a polyurethane.

The primer coating layer can have a thickness of from about 5 μm to about 20 μm, such as from about 7 μm to about 18 μm, or from about 10 μm to about 15 μm.

The base coating layer may comprise polyurethane-containing pigments. The base coating layer may further comprise at least one of carbon black, titanium dioxide, clay, mica, talc, barium sulfate, calcium carbonate, synthetic pigment, metallic powder, aluminium oxide, an organic powder, an inorganic powder, graphene, graphite, plastic beads, a colour pigment or a dye. The organic powder may, for example, be an acrylic, a polyurethane, a polyamide, a polyester or an epoxide.

The base coating layer may comprise a component selected from barium sulfate, talc, a dye and a colour pigment. In one example, the base coating layer comprises a colour pigment or a dye.

The base coating layer may further comprise a heat resistant material, such as a silica aerogel. The base coating layer can comprise a heat resistant material and a component as described above.

The base coating layer can have a thickness of from about 10 μm to about 25 μm, such as from about 15 μm to about 20 μm.

By using a base coating layer, other different protective layers can easily be deposited on the first layered surface. For example, when the first layered surface has been coated with an oxide layer, the use of a base coating layer may improve adhesion between different protective layers.

The powder coating layer may comprise a polymer selected from an epoxy resin, a poly(vinyl chloride), a polyamide, a polyester, a polyurethane, an acrylic and a polyphenylene ether.

In an example, the powder coating layer is an electrostatic powder coating layer. The powder coating layer may be electrostatically deposited or coated onto a first surface of the substrate and then the polymer may be cured.

The powder coating layer may further comprise a filler selected from carbon black, titanium dioxide, clay, mica, talc, barium sulfate, calcium carbonate, a synthetic pigment, a metallic powder, aluminium oxide, carbon nanotubes (CNTs), graphene, graphite, and an organic powder. The organic powder may, for example, be an acrylic, a polyurethane, a polyamide, a polyester or an epoxide. In one example, the fillers may be selected from talc, clay, graphene and high aspect ratio pigments.

The powder coating layer may be applied and may be cured at a temperature of 120° C. to 190° C.

The powder coating layer can have a thickness of from about 20 μm to about 60 μm, such as from about 30 μm to about 50 μm, or from about 35 μm to about 45 μm.

The top coating layer may comprise a bottom layer and a top layer coated or deposited on the bottom layer. The bottom layer may comprise a polyurethane polymer. The top layer may comprise a UV top coat. The UV top coat may, for example, be a resin, such as a polyacrylic resin, a polyurethane resin, a urethane acrylate resin, an acrylic resin or an epoxy acrylate resin.

When the top coating layer comprises a bottom layer and a top layer, then both the bottom layer and the top layer may be transparent. The top coating layer may be transparent.

The top coating layer can have a total thickness of from about 10 μm to about 25 μm, such as about 15 μm to about 20 μm.

The first layered surface may comprise multiple layers on the metal alloy substrate. The electrolytic sealing layer may then be deposited onto the first layered surface. In one example, a passivation layer may be deposited between the first layered surface and the electrolytic sealing layer.

The metal alloy substrate may be engraved to expose a non-oxidized chamfered edge on the metal alloy substrate. This process may remove part of the first layered surface previously applied.

### First Treated Surface

The metal alloy substrate may be pre-treated with one or more cleaning treatment followed by electrophoretic deposition, to form a first treated surface, before the application of an electrolytic sealing layer. The first treated surface may be treated with one or more of the cleaning treatments selected from degreasing, chemical polishing and deionized water cleaning. The cleaning treatment may even out the surface of the metal alloy substrate.

In one example degreasing is carried out in an ultrasonic vibration bath: comprising an alkaline cleaning process using 0.3-2.0 wt % sodium caseinate, sodium polyacrylate, sodium polyoxyethylene alkyl ether carboxylate, and sodium dodecyl sulfate in an ultrasonic vibration degreasing bath at pH 9-13 to remove organic impurities, grease and oil from a surface.

In one example, chemical polishing is carried out using 0.1-3 wt. % acid solution selected from hydrochloric acid, nitric acid, phosphoric acid, sulfuric acid and combinations thereof.

An electrophoretic polymer may then be applied to the cleaned metal alloy substrate surface. The electrophoretic polymer layer is formed by an electrophoretic deposition (EPD) process described herein.

The electrophoretic polymer may be selected from polyacrylic polymer, polyacrylamide-acrylic copolymer and epoxy-containing polymer.

The electrolytic sealing layer may then be deposited onto the first treated surface. In one example, a passivation layer may be deposited between the first treated surface and the electrolytic sealing layer.

The metal alloy substrate may be engraved to expose a non-oxidized chamfered edge on the metal alloy substrate. This process may remove part of the first treated surface.

### Process for Producing a Coated Metal Alloy Substrate

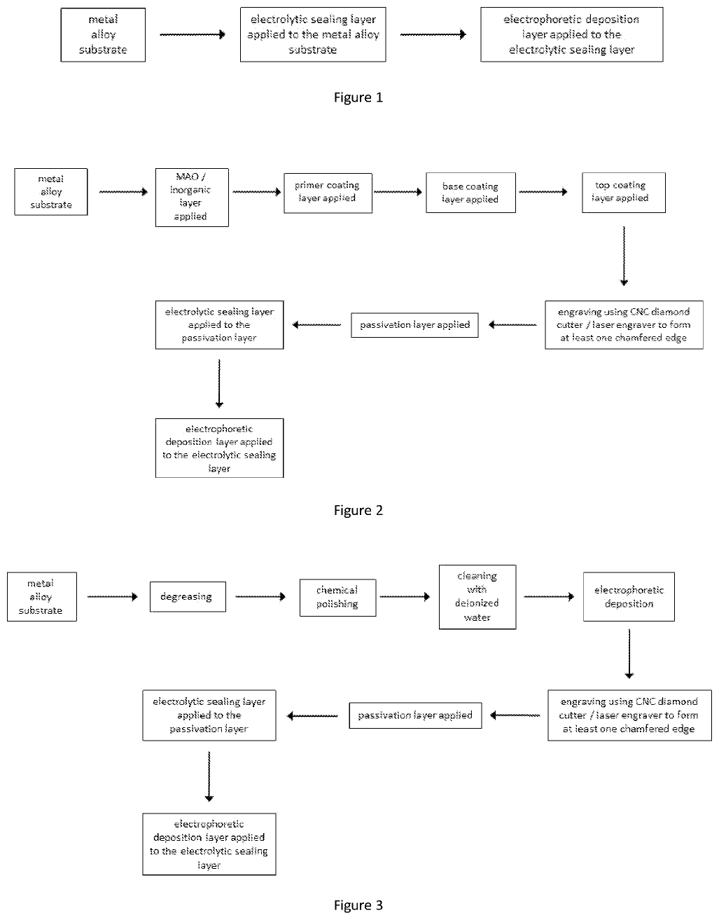

The present disclosure also relates to a process for producing a coated metal alloy substrate disclosed herein. The process for producing a coated metal alloy is described below and shown in the flow chart in FIG. 1.

In some examples there is provided a process for producing a coated metal alloy substrate for an electronic device comprising applying an electrolytic sealing layer on the metal alloy substrate; and applying an electrophoretic deposition layer on the electrolytic sealing layer.

An electrolytic sealing layer is applied to the metal alloy substrate. For example, the metal salt is applied by exposing the metal alloy surface to a metal salt solution and treating at 3 to 15 V for 0.5 to 5 minutes. For example, a voltage of 4 V, or 5 V, or 6 V, or 7 V, or 8 V, or 9 V, or 10 V, or 11 V, or 12 V, or 13 V, or 14 V may be applied for 1 minute, or 1.5 minutes, or 2 minutes, or 2.5 minutes, or 3 minutes, or 3.5 minutes, or 4 minutes, or 4.5 minutes. In one example, zinc oxide is applied by exposing the metal alloy surface and zinc oxide to 3 V for 2 minutes. In one example, chromium hydroxide is applied by exposing the metal alloy surface and chromium hydroxide to 10 V for 1 minute.

An electrophoretic layer is then deposited on at least part of the electrolytic sealing layer. To carry out the electrophoretic deposition, the metal alloy substrate is made an electrode of an electrochemical cell. The electrochemical cell also has an inert electrode as the counter electrode and an electrolyte comprising the electrophoretic polymer. A potential difference is applied across the electrodes of the electrochemical cell to deposit the electrophoretic polymer over the coating layer. The electrolyte may have a concentration of from about 1 wt. % to about 25 wt. %, such as from about 5 wt. % to about 20 wt. %, or from about 10 M.% to about 15 wt. % of the electrophoretic polymer. The polymer, in general, has ionizable groups. When the polymer is a negatively charged material, then it will be deposited on the positively charged electrode (anode). When the polymer is a positively charged material, then it will be deposited on the negatively charged electrode (cathode).

In some examples, a passivation layer may be applied to the metal alloy before applying the electrolytic sealing layer. The passivation layer may be sprayed, rollered, dipped, or brushed onto the metal alloy surface.

In some examples, the metal alloy substrate may be engraved to form a chamfered edge. The chamfered edge formed by the engraving may be an exposed non-oxidized surface of the substrate. This process removes a part of the any coated surface, including, for example, any oxidized layers to expose a shiny surface of the underlying substrate. Part of the first layered surface or the first treated surface of the substrate is retained after the engraving process.

Engraving the metal alloy substrate to form at least one chamfered edge may be carried out to form a predefined pattern or shape. The engraving process may allow the formation of patterns that will provide a surface of the chamfered edge with a texture or finish that is different to the texture or finish of the metal alloy substrate that has not been engraved.

Engraving the metal alloy substrate to form at least one chamfered edge may be carried out using a Computer Numeric Control (CNC) diamond cutter or a laser engraver. Using this process, parts of the metal alloy substrate may be cut away and each resulting chamfered edge may form an edge, a sidewall, a logo, a gap for a click pad, a gap for a fingerprint scanner.

In one example, as shown in the flow chart of FIG. 2, the metal alloy substrate is treated with MAO to form a micro-arc oxide layer, or an inorganic layer is applied as a non-transparent passivation layer. In this example, the primer coating layer, a base coating layer and a top coating layer is applied. The metal alloy substrate is then engraved with CNC laser engraving to form a chamfered edge. The chamfered edge is then treated with a passivation layer, an electrolytic sealing layer and an electrophoretic deposition layer.

In one example, as shown in the flow chart of FIG. 3, the metal alloy substrate is cleaned by degreasing, chemical polishing, cleaning with deionized water before applying an electrophoretic deposition layer. The metal alloy substrate is then engraved with CNC laser engraving to form a chamfered edge. A passivation layer, an electrolytic sealing layer and an electrophoretic deposition layer is then applied to the chamfered edge. In this example, the passivation layer, the electrolytic sealing layer and the electrophoretic deposition layer do not adhere to the first layered surface.

In one example, no further coating is applied after treating the metal alloy substrate with an electrolytic sealing layer and an electrophoretic deposition layer.

Each layer may be applied to achieve a desired thickness. The thickness of each layer can be measured after it has been applied using, for example, a micrometre screw gauge or scanning electron microscope (SEM).

### Electronic Device

The electronic device of the present disclosure may be a computer, a laptop, a tablet, a workstation, a cell phone, a portable networking device, a portable gaming device and a portable GPS.

The electronic device has an electrical circuit, such as a motherboard or display circuitry. The housing may be external to the electrical circuit.

### Housing

As described in the present disclosure, an electronic device may have a housing. In some examples there is provided an electronic device having a housing, wherein the housing comprises a metal alloy substrate, an electrolytic sealing layer deposited on the metal alloy substrate; and an electrophoretic deposition layer deposited on the electrolytic sealing layer. The housing comprises a metal alloy substrate disclosed herein. The metal alloy substrate can be light-weight and may provide a durable housing. The housing of the present disclosure may have cosmetic features that are visually appealing to a user, such as an attractive surface finish. The housing according of the present disclosure may have a pleasant texture and not have an orange peel finish. An orange peel finish is determined by visual examination. If the texture of the surface resembles the surface of an orange it is considered to have an orange peel finish.

The housing may provide an exterior part of the electronic device, such as a cover or a casing of the electronic device. The housing may include a support structure for an electronic component of the electronic device. The housing may include a battery cover area, a battery door, a vent or combinations thereof.

The housing may provide a substantial part of the cover or the casing of the electronic device. The term “substantial part” in this context refers to at least about 50%, such as at least about 60%, at least about 70%, at least about 80% or at least about 90%, of the total weight of the cover or the casing. The housing may provide the entire cover or casing of the electronic device.

The housing can be a cover, such as a lid, the casing or both the cover and the casing of the electronic device. The casing may form a bottom or lower part of the cover of the electronic device. For example, the housing is the casing of a laptop, a tablet or a cell phone.

The housing may comprise a dual surface metal alloy substrate, wherein one of the surfaces is a chamfered edge. The main non-engraved surface of the metal alloy substrate may provide a bezel for a display screen, a casing, or wrist rest for a keyboard.

The chamfered edge may provide an edge or peripheral area in the housing for a touchpad, a fingerprint scanner, a trackball, a pointing stick, or a button, such as a mouse button or a keyboard button.

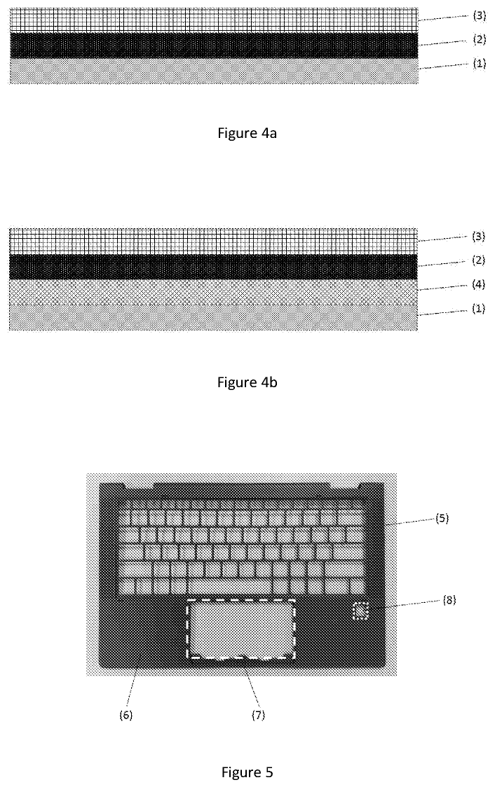

Examples of housings of the present disclosure are shown in FIGS. 4a and 4b, which are partial cross sections through the housing. The housing shown in FIG. 4a has a metal alloy substrate (1) with an electrolytic sealing layer (2) and an electrophoretic deposition layer (3). In a further example, the housing shown in FIG. 3b has a metal alloy substrate (1) with a passivation layer (4), an electrolytic sealing layer (2) and an electrophoretic deposition layer (3).

FIG. 5 shows an example of a housing of the present disclosure. The housing is a casing (5) for a keyboard of a laptop. The non-engraved coated surface of the metal alloy substrate (6) provides a wrist rest and cover for the laptop. Chamfered edges form further surfaces such as (7) and (8). The surfaces of this housing have an attractive appearance and provide a pleasant tactile surface with no visible orange peel effect. Along with a high metallic lustre, the surfaces are corrosion resistant and have a durable coating.

### EXAMPLES

The following illustrates examples of the methods and other aspects described herein. Thus, these Examples should not be considered as limitations of the present disclosure, but are merely in place to teach how to make examples of the present disclosure.

### Example 1

A keyboard casing for a laptop was manufactured from a magnesium alloy substrate comprising the magnesium alloy AZ31B, which comprises, based on the weight of the total alloy: Al: 2.5-3.5 wt. %, Zn: 0.6-1.4 wt. %, Mn: 0.2 wt. %, Si: 0-1 wt. %, Cu: 0.05 wt. %, Ca: 0.04 wt. %, Fe: 0.005 wt. %, Ni: 0.005 wt. % and the remainder being Mg and inevitable impurities.

An oxidized surface layer was formed on the magnesium alloy substrate by micro-arc oxidation. The oxidized surface layer was then coated with a primer coating layer of polyester polyurethane. The primer coating layer was coated with a base coating layer of polyurethane and a top coating layer of urethane acrylate.

Chamfered edges were then cut into the substrate by using a CNC cutting process to expose a non-oxidised surface of the coated metal alloy substrate to cut an opening in the casing for a touchpad and cleaned with deionized water.

An electrolytic sealing layer is then applied to the chamfered edge by immersing the Mg alloy substrate in a solution of zinc oxide and sodium silicate in deionized water and treating at 5 V for 1 minute.

Using electrophoretic deposition an electrophoretic deposition layer comprising 10 wt. % polyacrylic polymer, 5 wt % pigment yellow 191, 0.5 wt % sodium polyacrylate, and 0.3 wt. % glutaraldehyde, based on the total weight of the electrophoretic deposition layer, was applied onto the electrolytic sealing layer. The substrate was then heated at 170° C. for 45 minutes.

The magnesium alloy substrate exhibited an attractive metallic lustre and a pleasant tactile surface with no orange peel effect. The magnesium alloy substrate was found to exhibit corrosion resistance properties in all parts of the substrate including the chamfered edges.

### Example 2

In a further example a keyboard casing for a laptop was coated as in Example 1, with a further transparent passivation layer applied after formation of the chamfered edges and before application of the electrolytic sealing layer. The transparent passivation layer applied comprised a chelated metal complex where the chelating agent is DTTPH and the metal ion is zinc.

The coated metal alloy substrate of this example exhibited the properties of the metal alloy substrate according to Example 1 and additionally enhanced corrosion resistance and maintenance of metallic lustre appearance.

1. A coated metal alloy substrate for an electronic device comprising:
an electrolytic sealing layer deposited on the metal alloy substrate; and
an electrophoretic deposition layer deposited on the electrolytic sealing layer.

2. The coated metal alloy substrate according to claim 1, wherein the electrolytic sealing layer comprises a metal salt selected from zinc oxide, chromium hydroxide, potassium hydroxide, sodium carbonate, sodium silicate and combinations thereof.

3. The coated metal alloy substrate according to claim 1, wherein the electrophoretic deposition layer comprises an electrophoretic polymer selected from polyacrylic polymer, polyacrylic-amide polymer, polyacrylamide-acrylic copolymer and epoxy-containing polymer.

4. The coated metal alloy substrate according to claim 1, wherein the electrophoretic deposition layer has a thickness of at least 5 μm.

5. The coated metal alloy substrate according to claim 1 further comprising a passivation layer between the metal alloy substrate and the electronic sealing layer, wherein the passivation layer comprises a chelating agent and a metal ion or chelated metal complex thereof.

6. The coated metal alloy substrate according to claim 5, wherein the chelating agent is selected from ethylenediaminetetraacetic acid, ethylenediamine, nitrilotriacetic acid, diethylenetriaminepenta(methylenephosphonic acid), nitrilotris(methylenephosphonic acid), 1-hydroxyethane-1,1-diphosphonic acid and phosphoric acid, and the metal ion is selected from an aluminium ion, a nickel ion, a chromium ion, a tin ion, an indium ion, and a zinc ion.

7. The coated metal alloy substrate according to claim 1, wherein the coated metal alloy substrate comprises at least one chamfered edge.

8. The coated metal alloy substrate according to claim 1, wherein the metal alloy substrate comprises a metal alloy selected from an aluminium alloy, a magnesium alloy, a lithium alloy, a titanium alloy and stain steel.

9. The coated metal alloy substrate according to claim 1, wherein the metal alloy substrate is an insert molded metal substrate comprising a plastic insert.

10. The coated metal alloy substrate according to claim 1, wherein the electronic device is selected from a computer, a laptop, a tablet, a cell phone, a portable networking device, a portable gaming device and a portable GPS.

11. A process for producing a coated metal alloy substrate for an electronic device comprising:
applying an electrolytic sealing layer on the metal alloy substrate; and
applying an electrophoretic deposition layer on the electrolytic sealing layer.

12. The process for coating a metal alloy substrate according to claim 11, comprising engraving the metal alloy substrate to form at least one chamfered edge prior to applying the electrolytic sealing layer.

13. The process for coating a metal alloy substrate according to claim 11, wherein the substrate bearing the electrolytic sealing layer is made an electrode of an electrochemical cell, wherein the electrochemical cell has an inert electrode as the counter electrode and an electrolyte comprising the electrophoretic polymer.

14. The process for coating a metal alloy substrate according to claim 13, wherein a potential difference is applied across the electrodes of the electrochemical cell to deposit the electrophoretic polymer over the passivation layer.

15. An electronic device having a housing, wherein the housing comprises:
a metal alloy substrate;
an electrolytic sealing layer deposited on the metal alloy substrate; and
an electrophoretic deposition layer deposited on the electrolytic sealing layer.
